(19) United States
(12) Patent Application Publication
(10) Pub. No.: US 2006/0018085 A1
(43) Pub. Date: Jan. 26, 2006

(54) Apparatus for containing solid state electronic circuits and components and having the appearance of a vacuum tube

(76) Inventor: Sean M. Kelly, Yorba Linda, CA (US)

Correspondence Address: Leonard Tachner;a professional law corporation, Suite 38-E, 17961 Sky Park Circle, Irvine, CA, 92614, US

(21) Appl. No.: 11/186,054

(22) Filed: Jul. 21, 2005

Related U.S. Application Data
(60) Provisional application No. 60/590,096, filed on Jul. 21, 2004.

(51) Int. Cl. H03F 21/00

(52) U.S. Cl. 361/600; 381/120

(57) ABSTRACT

A simulated vacuum tube and vacuum tube apparatus which employs solid-state components within a vacuum tube enclosure. A transparent or translucent glass or plastic tubular enclosure contains and isolates an operating environment. This unique enclosure creates a visually pleasing device while also providing an independently managed environment that may be entirely isolated from the primary outer enclosure of the equipment. In addition, the transparent or translucent tube permits transmission of optical signals, visual indicators and displays, as well as visual inspection of components and printed circuit boards for troubleshooting and repair. Several different illustrative embodiments are disclosed herein.

### CROSS-RELATED APPLICATIONS

This application claims priority from U.S. Provisional Patent Application Ser. No. 60/590,096 filed Jul. 21, 2004.

### BACKGROUND OF THE INVENTION

1. Field of the Invention

The present invention relates primarily to the packaging of electronic components and more specifically to a transparent or translucent enclosure configured as a facsimile of a traditional vacuum tube which may contain and isolate an operating environment in which are operated electronic components. Secondarily, the invention relates to electronic device topologies and schemas rendered newly feasible as a result of the primary tube invention.

2. Background Art

Prior to about 1970, the vast majority of electronic equipment such as stereos, televisions, communication systems and the like, used vacuum tubes. For those who may be too young to remember them, vacuum tubes were evacuated, generally cylindrical, glass enclosures having a source of electrons (i.e., heated cathode) and one or more other metal electrodes (i.e., anode, screen, plate, etc.) forming diodes, triodes, pentodes, etc. for controlling and amplifying electrical signals. Typically, they had electrical contact pins at their bottoms and these pins mated with female receptacles which were hard-wired into an electrical circuit. These tubes had glowing heaters and cathodes which would emit light clearly visible through the glass enclosures. Consequently, one could clearly see an attractive series of glowing vacuum tubes when looking inside a stereo amplifier or television chassis.

Today, the vacuum tube is a distant memory, an interesting relic of the recent past; something anyone younger than forty years old has probably never seen. Nevertheless, there is a certain nostalgia associated with vacuum tubes, particularly with the “over-forty” crowd who still have memories of the “good-old-days” when vacuum tube equipment was in wide use. Some die-hard audiophiles still believe, in fact, that vacuum tube audio amplifiers are superior to solid state amplifiers in common use today and they are willing to pay a premium to acquire a pair of the few remaining such amplifiers.

### SUMMARY OF THE INVENTION

The present invention, in its preferred embodiment, is a simulated vacuum tube and vacuum tube apparatus which employs solid-state components within a vacuum tube enclosure. A transparent or translucent glass or plastic tubular enclosure contains and isolates an operating environment. This unique enclosure creates a visually pleasing device while also providing an independently managed environment that may be entirely isolated from the primary outer enclosure of the equipment. In addition, the transparent or translucent tube permits transmission of optical signals, visual indicators and displays, as well as visual inspection of components and printed circuit boards for troubleshooting and repair. Several different illustrative embodiments are disclosed herein.

In a first embodiment, the vacuum tube is employed to house two elongated printed circuit boards sandwiching a heat conductive plate. In this embodiment, the two PCB's each contain driver field effect transistors acting as the final stage of an audio-amplifier circuit. The FETs are faced toward the heat conductive plate. The front side of each PCB contains an array of LED's or infrared transceivers. These components allow for monitoring status or performance or for infrared communication with the user or the system, thereby reducing the number of connectors and circuit traces that are required. The tube contains an environment of purified air and/or inert gas(es) enclosed at or below atmospheric pressure

In a second embodiment, the tube contains a tubular printed circuit board (PCB) made of composite material with circuit traces applied using flexible silk-screening. This affords the PCB the advantage of ‘flexure-points’ to relieve thermal expansion and other stresses. The inner surface is used for resistors, transistors, FETs and other heat-producing components. Their confined heat facilitates convective forces. The outer surface of the PCB is used for visual display components (i.e., LEDs) or other elements that don't produce large amounts of heat. Using optoelectrics or an encapsulated wireless networking transceiver, this embodiment can process complex signals with a minimum number of pin-connectors. As an audio amplifier, it can receive, process, re-transmit music signals or other system data, such as synchronization codes. A heat-sink or peltier device may be placed on top, beside or around the outer surface to facilitate convection. Connectors may be PCB-type, or PIN-type or other.

In a third embodiment, the glass/plastic outer tube is filled with a cooling fluid. As fluid inside the PCB is heated by the operating components, it rises up the tube. The outer tube wall transmits heat to the surrounding air, the fluid then descends to a reservoir at the base through convective forces. The tube may be configured at less-than-atmospheric pressure, facilitating a phase-change in the convective process as well. This is similar to heat-pipes except that this is a single-chamber approach that puts the component(s) inside the condensing chamber. Some cooling fluids already exhibit this phase-change characteristic without the need for a vacuum. A heat sink or Peltier device may also be placed on top, beside or around the outer surface of the tube to even further facilitate convection. A small pump or fan may be built into the tube to further facilitate the constant flow of the cooling medium (fluid, vapor or gas). In operation, the unit's ‘percolating’, pulsating glow will have visual appeal, reminiscent of science fiction movies or ‘Cerenkov Radiation’; the blue glow that is seen in the water of nuclear reactors.

In a fourth embodiment, a single-channel audio-amplifier, connectors have been virtually eliminated. Power is transferred by an induction coil, signals are received through opto-electric and/or wireless network transceiver(s), and the output signal is sent through the metal base. A heat-conductive plate connects to a heat sink above. An insulating material between the two halves of the metal base establishes two discrete electrical paths that serve as the connectors for the output-signal (to the speakers).

In a fifth embodiment, a simple form of tube contains several printed circuit boards (PCB's), each available to the system as an optional and distinct circuit topology. An encapsulated relay module at the base connects the appropriate (selected) PCB to the input/output connectors below. This affords the option of several types of circuitry, without hard-wiring of the more expensive and otherwise redundant components (transistors, integrated chips, etc . . . ). This embodiment could also be used to isolate sensitive boards or components from heat, moisture, dust, or vibration, using single or plural-wall construction.

A sixth embodiment includes a bank of discrete Single-Channel Amplifier Tubes. This system demonstrates the tubes' modularity. First a signal processing tube receives an audio signal (perhaps through wireless or optical interface). Next, a resource-manager-tube configures the driver-stage for optimal performance, actually choosing from several different types of circuits, all of which draw from a standard pool of component and/or board-level resources. A circuitry tube isolates in fully modular form the raw circuit traces for each type of circuit topology. This tube may contain absolutely nothing except for printed circuit boards (raw trace, but no components). The resource manager tube, along with its chosen circuitry, routes the signal to the driver-stage resources in a tube array. These array tubes are standard and may be uniform. This dynamic approach may be used to bridge several discrete single-channel amplifiers, reconfiguring them into a single, more powerful circuit. Similarly, this approach may be used to selectively reassign final-stage FET's to a single unified output stage.

A seventh embodiment is a multi-channel “surround-sound” system comprised of eight modular units (previously described as embodiment six). The modules are interconnected by several “bridge-channels”, with which the system can “lend” amplifier tubes to other channels/modules when needed. Similarly, the user (notably a lay-person) can relocate tubes from one module to another, depending upon his/her musical taste, planned entertainment, and budget. The user can increase the system's total wattage by merely purchasing and inserting an additional tube into an available connector “socket”. This embodiment facilitates a lower price-point in the marketplace, as users can buy as much power as they can afford and upgrade later. This embodiment also reduces total cost of ownership, since a lay-user can troubleshoot and replace the modular components himself/herself. This embodiment also offers the strong aesthetic appeal of “device-repetition” as a complex “forest” of glowing tubes entrances the observer during operation. The dynamic resource management described herein is made more feasible by the continuing development/refinement of digital amplifiers, which can divide a signal across multiple components without significant loss of quality.

An eighth embodiment consists of a retrofit kit to transform an existing (non-powered) speaker into a tube-powered speaker. The tube, a self-contained single-channel amplifier, is allowed to protrude from the top of the speaker cabinet for its visual appeal. Two simple wires attach the amplifier's output to the signal connectors in the back of the speaker cabinet. Wires also connect the tube assembly to an external power supply. Signal may be delivered to the tube using conventional speaker cables, by opto-electric transceiver or by wireless (radio-frequency) network.

### BRIEF DESCRIPTION OF THE DRAWINGS

The aforementioned objects and advantages of the present invention, as well as additional objects and advantages thereof, will be more fully understood herein after as a result of a detailed description of a preferred embodiment when taken in conjunction with the following drawings in which:

FIG.1 is a front view of a first embodiment of the invention;

FIG. 2 is a back view of a PCB of the first embodiment;

FIG. 3 is a front view of the PCB of FIG. 2;

FIG. 4 is a side view of the first embodiment;

FIG. 5 is a three-dimensional view of the tube contents (i.e., two PCBs sandwiching a heat conductor plate) of the first embodiment;

FIG. 6 is a top view of the first embodiment;

FIG. 7 is a side view of a second embodiment;

FIG. 8 is a top view of the second embodiment;

FIG. 9 is a front view of the second embodiment;

FIG. 10 is an exploded view of an external heat sink assembly of the second embodiment;

FIG. 11 is an assembled view of the assembly of FIG. 10;

FIG. 12 is a side view of the fourth embodiment of the invention;

FIG. 13 is a bottom view of the fourth embodiment;

FIG. 14 is a bottom view similar to that of FIG. 13, but showing an interior inductor coil for receiving power;

FIG. 15 is a side view of a fifth embodiment of the invention;

FIG. 16 is a side view of embodiment 6, a modular assembly of tubes in accordance with the present invention;

FIG. 17 is a three-dimensional (front) view of embodiment 7, a multi-channel array of the module shown in FIG. 16;

FIG. 18 is a front view of an eighth embodiment; and

FIG. 19 is a cut-away side-view of the eighth embodiment.

### DETAILED DESCRIPTION OF PREFERRED EMBODIMENTS

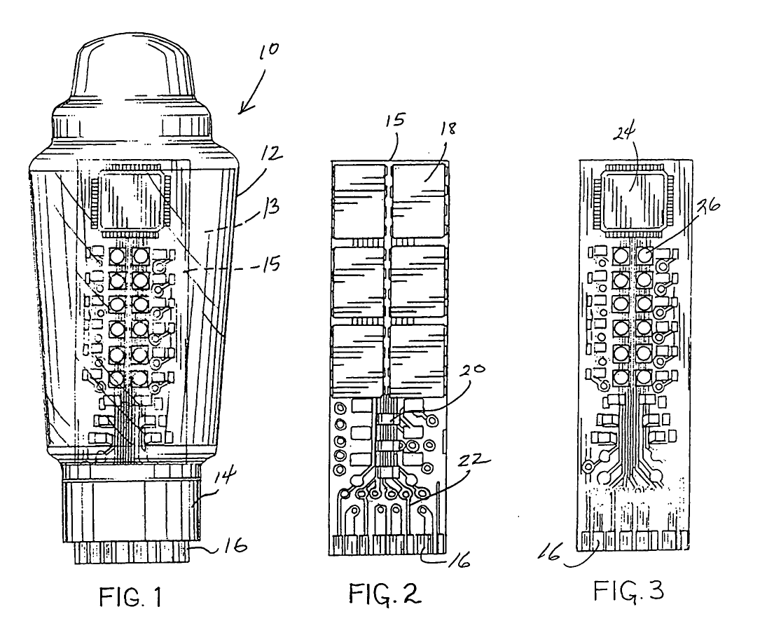

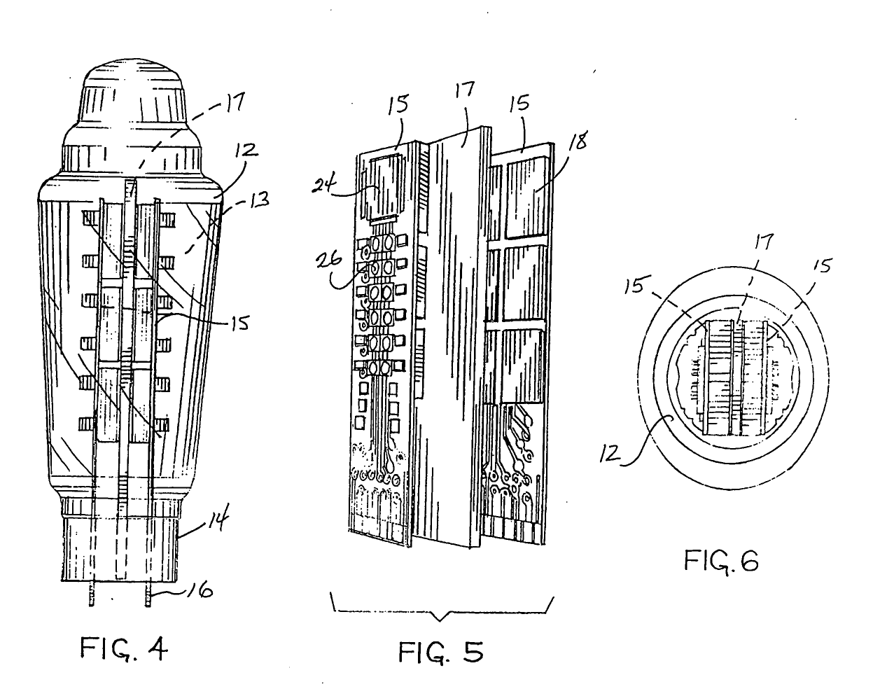

Referring to the accompanying figures and initially to FIGS. 1-6 in particular, it will be seen that a first embodiment of the invention comprises a vacuum tube assembly 10 having a glass or plastic transparent or translucent tube 12 preferably (although not necessarily) having an evacuated interior 13. Mounted inside tube 12 are a pair of printed circuit boards (PCBs) 15 sandwiching a planar heat conductor plate 17. The PCBs each have field effect transistors (FETs) 18, other components 20, DSP 24, LEDs 26 and various circuit traces 20, the latter connecting to a plurality of pins 16 in an external base 14.

In this embodiment, the two PCBs each contain driver FETs (back) to act as the final stage of an audio-amplifier circuit. The FETs are faced towards the heat plate, arranged in a two PCB ‘sandwich’. The front side of each PCB contains an array of LED's or infrared transceivers. These components allow for human monitoring of status/performance or infrared communication with user or system. This reduces the number of required connectors and circuit traces.

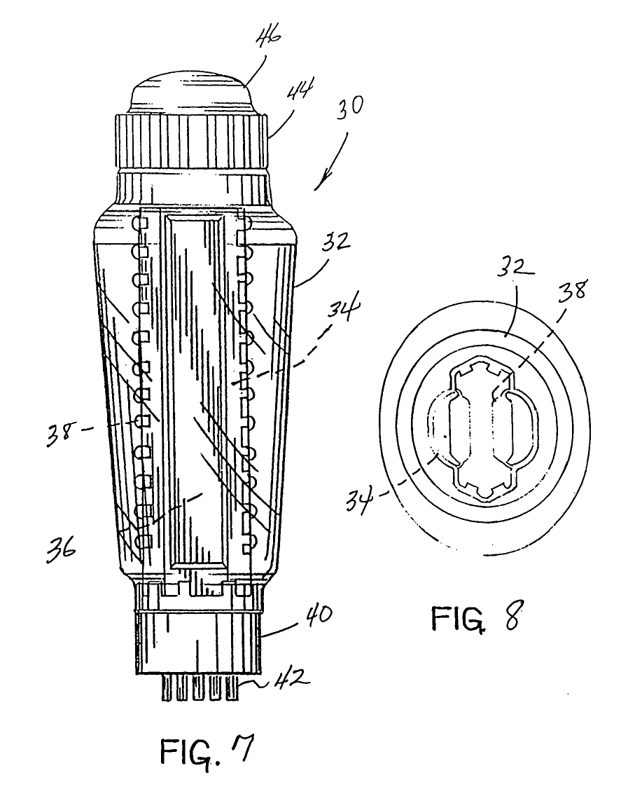

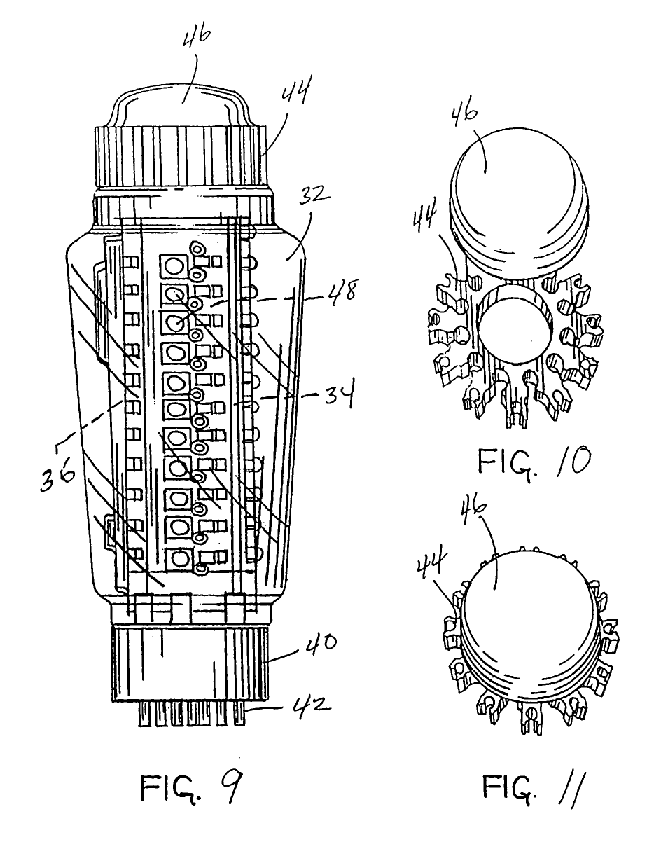

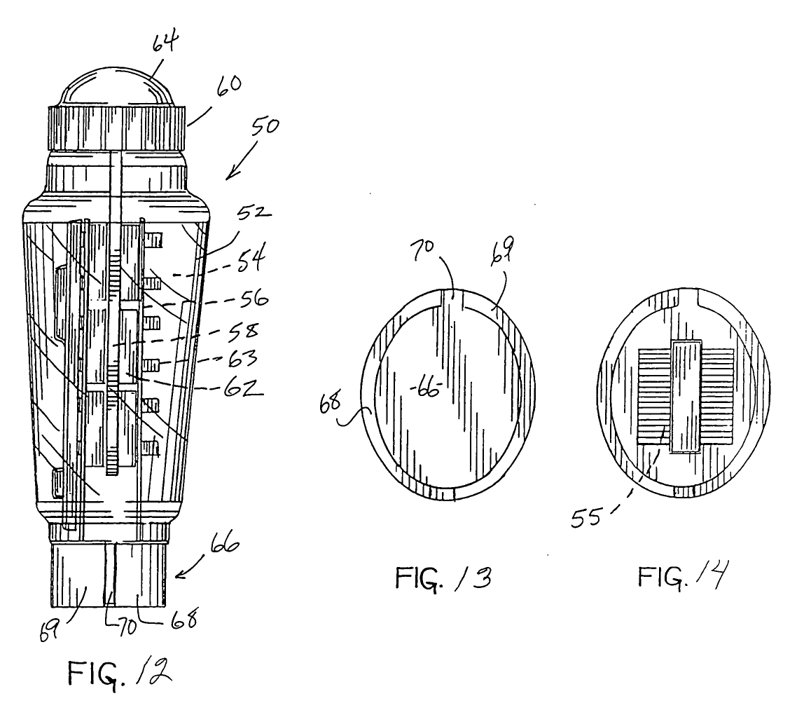

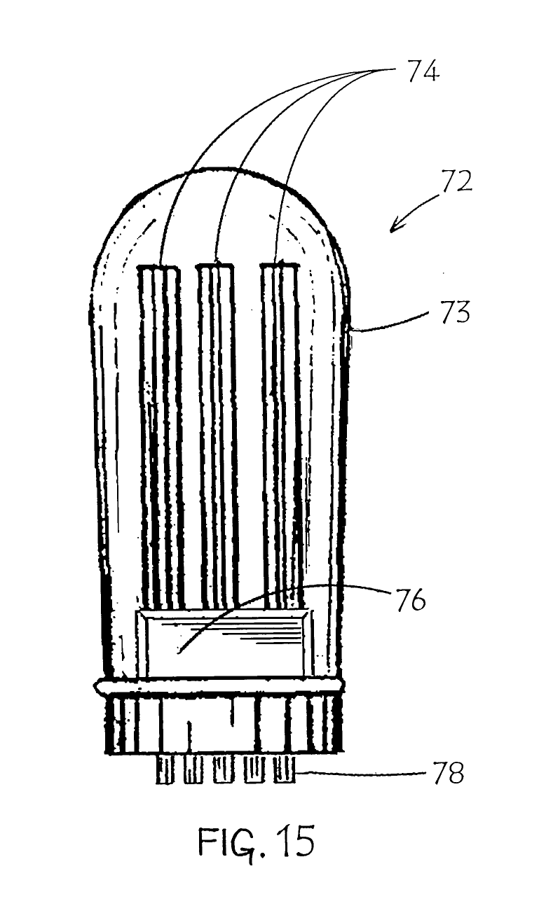

Turning now to FIGS. 7-11, it will be seen that a vacuum tube assembly 30 has a tube 32 enclosing a tubular printed circuit board (PCB) 34 made of composite material with circuit traces applied using flexible silk-screening.

This non-planar form affords the PCB the advantage of ‘flexure-points’ to relieve thermal expansion and other stresses. Upon this PCB are mounted a wireless transceiver 36 and other components 38 including LEDs 48 connected to pins 42 through a base 40. The inner PCB surface is used for resistors, transistors, FETs and other heat-producing components. Their confined heat facilitates convective forces. The outer surface of the PCB is used for visual display components (such as LEDs) or other elements that don't produce large amounts of heat. This embodiment is characterized by external heat sinks in the form of finned cylinder 44 and a domed cap 46.

Using opto-electrics or an encapsulated wireless networking transceiver, this embodiment can process complex signals with a minimum number of pin-connectors. As an audio amplifier, it can receive, process, re-transmit music signals or other system data, such as synchronization codes. The glass/plastic outer tube may be filled with a cooling fluid. As fluid inside the PCB is heated by the operating components, it rises up the tube. The outer tube wall transmits heat to the surrounding air, and falls to a reservoir in the base (also through connective forces). The tube may be configured at less-than-atmospheric pressure, facilitating a phase-change in the convective process as well. This is similar to heat-pipes except that this is a single-chamber approach that puts the component inside the heat pipe. Some cooling fluids already exhibit this phase-change characteristic without the need for a vacuum. Gaps at the base of the PCB allow cooling fluid to flow back into the center for re-convection. Connectors could be PCB-type, or PIN-type or other. A heat sink or Peltier device may also be placed on top, beside or around the outer tube to even further facilitate the convection. A small pump or fan could be built into the tube to further facilitate the constant flow of the cooling medium (fluid, vapor or gas). In operation, the unit's ‘percolating’, pulsating glow will have visual appeal, reminiscent of science fiction movies or ‘Cerenkov Radiation’:The blue glow that is seen in the water of nuclear reactors.

In the embodiments of FIGS. 12-14, a vacuum tube assembly 50 comprises a tube 52 having an isolated or evacuated interior 54 in which are positioned a pair of PCBs 56 sandwiching a conductor heat plate 58 which extends upward toward the top of the tube which has external heat sinks 60 and 64. The high heat generating components 62 are mounted on the heat plate side of the PCBs while the low heat generating components 63 are mounted on the other side of the PCBs. This embodiment provides an internal inductor coil 55 and external semi-circular electrical connectors 68, 69 in base 66. The connectors 68, 69 are separated by an insulating gap 70.

In this embodiment, input and power connectors have been virtually eliminated. Power is transferred by induction, signals are received through optoelectric and wireless network, and the output signal (to the speakers) is sent through the two connectors around the metal base. The heat-plate connects to the heat sink above and additional heat is passively transferred through the base below.

In FIG. 15 there is shown a simplified circuitry tube 72, in which a glass or plastic outer tube 73 contains printed circuit boards 74, an encapsulated relay 76, and connector pins 78.

In this embodiment, the relay selects from an array of circuit topologies (printed or constructed on PCBs 74) according to a controlling signal delivered through the connectors (pin-type or other). These PCBs may contain nothing except raw circuit-traces, establishing topologies to be applied to electronic component resources mounted elsewhere. This allows a single pool of component-level resources to be used flexible in various circuits for a wider range of performance characteristics, establishing economies of space and cost. Similarly, this embodiment could incorporate integrated circuitry chip(s) or encapsulated (“potted”) circuitry containing both circuit-traces and solid-state relays.

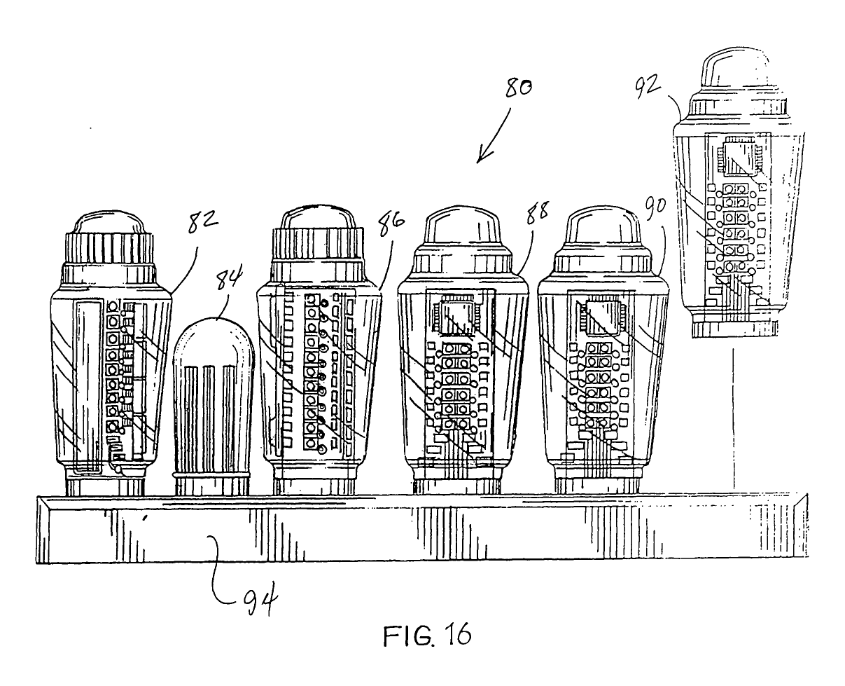

In FIG. 16 there is shown an audio processor/amplifier module 80 comprising a signal processing tube 82, a circuitry tube 84, a resource manager tube 86, and output array tubes 88, 90 and 92. The tubes are mounted on a tube interface 94.

This embodiment illustrates the tubes ‘modularity’. First the signal processing tube 82 receives the audio signal (perhaps through wireless or optical interface). Next, the resource-manager-tube 86 configures the driver-stage for optimal performance, actually choosing from several different types of circuits, all of which draw from a standard pool of component and/or board-level resources. The circuitry tube 84 isolates in fully modular form the raw circuit traces for each type of circuit topology. The resource manager tube 86, along with its chosen circuitry (in tube 84), routes the signal to the driver-stage resources in the tube array. These array tubes 88, 90 and 92 are standard and may be uniform. This modular and fully dynamically-reconfigurable device can achieve higher wattage capacity by bridging discrete amplifier circuits, final-stage resources, or manually by the mere addition of another tube 92.

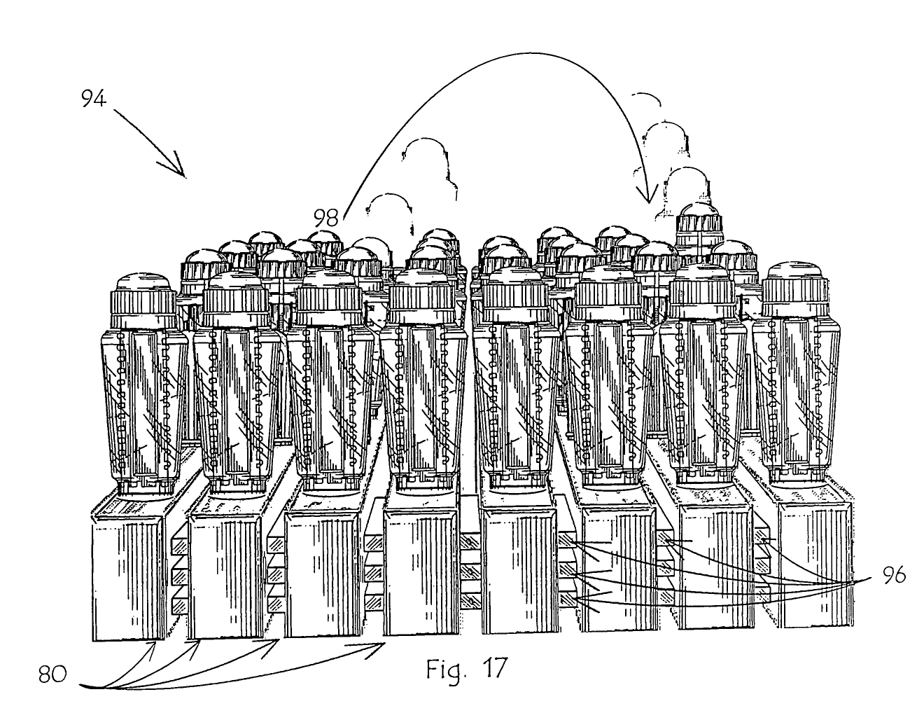

In FIG. 17 there is shown a multi-channel “surround-sound” system 98, comprised of eight of the modular units 80 as described in FIG. 16., interconnected by bridge channels 96.

In this embodiment, the multi-channel system receives a wireless or opto-electric control signal from a computer or other digital (or partially digital) media player device (above and beyond the audio content signal). Based upon instructions in this DIGITAL-DIALOG™ control signal (or an on-board manual selector switch), the multi-channel system can “lend” amplifier tubes from one channel/module to another when needed. This DYNAMIC-BRIDGING™ approach, is only now possible with the advent of digital media-players and digital amplifiers. Similarly, the user (notably a lay-person) can relocate tubes from one module to another, depending upon his/her musical taste, planned entertainment, and budget. Similarly, the controlling device can manage the gain and/or assignment of these discreet amplifier(s) so as to make the best usage of an individual speaker of a speaker array and/or to maintain these amplifiers or groups of these amplifiers in the most beneficial portion of their performance curves (eg THD vs. power and THD vs. frequency.

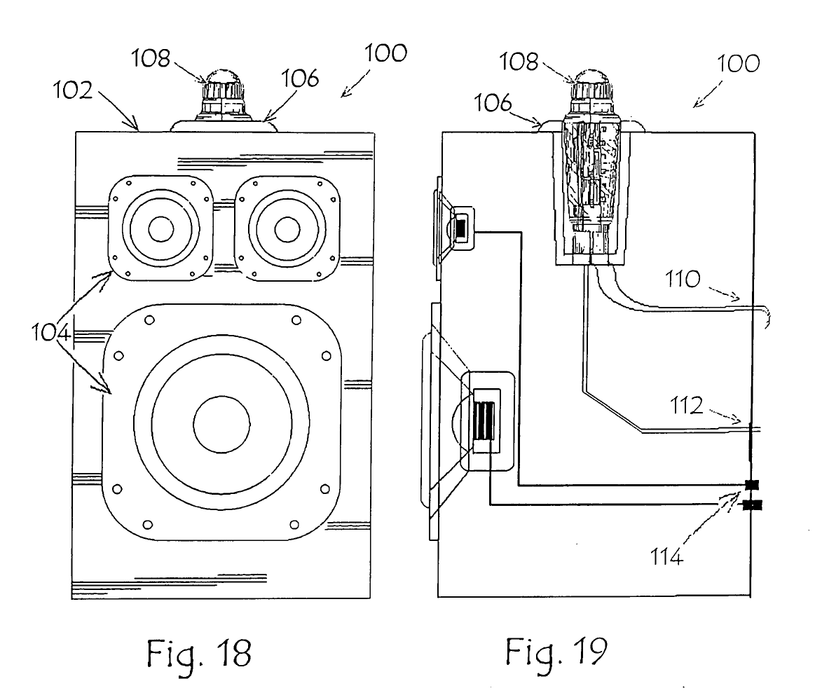

Turning now to FIGS. 18-19, there is shown a powered speaker assembly 100, consisting of a pre-existing cabinet enclosure 102, speakers 104, a retrofit amplifier socket 106, and a single-channel amplifier tube 108. The retrofit kit can be added to the pre-existing (non-powered) speaker assembly by the mere drilling of a few holes in the cabinet. In this embodiment, the tube is allowed to protrude, providing visual aesthetic appeal. The retrofit amplifier socket is inserted through a top-hole, and the wires for speaker signal 110 and external power source 112 are routed through small holes in the cabinet's back. The signal wires (to the speakers) connect to the normal rear connectors 114 of the pre-existing assembly.

This embodiment facilitates the consumer trend towards powered speakers by reducing the cost of upgrade and eliminating the stigma often associated with “do-it-yourself” (DIY) upgrades. This retrofit upgrade will establish additional aesthetic appeal for the pre-existing speaker assembly based upon the visibility of the tube. This embodiment demonstrates the highest order of flexibility in this invention, as a self-contained single-tube implementation can be added to an existing environment/application by a lay-person.

Having thus disclosed various alternative embodiments of the invention, it will now be apparent that numerous modifications and/or additions may be made thereto without deviating from the novel features thereof. Accordingloy, the scope hereof will be determined solely by the appended claims and their equivalents.

I claim:

1. An apparatus comprising:
an electronic circuit contained within a transparent tubular envelope configured to have the appearance of a vacuum tube.

2. The apparatus recited in claim 1 wherein said electronic circuit is installed on a printed circuit board and comprises at least one solid state device.

3. The apparatus recited in claim 2 wherein said at least one solid state device receives signals transmitted optically through said transparent tubular envelope.

4. The apparatus recited in claim 1 wherein said tubular envelope contains a cooling medium for transferring heat away from said electronic circuit.

5. The apparatus recited in claim 1 further comprising a heat sink in contact with said tubular envelope for transferring heat away from said electronic circuit.

6. The apparatus recited in claim 1 wherein said tubular envelope is sealed to provide an isolated interior and wherein said interior is at a pressure below atmospheric pressure.

7. The apparatus recited in claim 1 further comprising an induction coil for receiving electrical power for use in said electronic circuit.

8. The apparatus recited in claim 1 further comprising a plurality of distinct electronic circuits contained within said tubular envelope and a relay switch for selecting at least one of said distinct electronic circuits for operation.

9. The apparatus recited in claim 1 wherein said electronic circuit comprises an audio amplifier.

10. The apparatus recited in claim 1 wherein said electronic circuit comprises a digital amplifier.

11. The apparatus recited in claim 1 wherein said electronic circuit comprises a unitary component of a multiple component digital amplifier.

12. The apparatus recited in claim 1 wherein said electronic circuit comprises a single-channel audio amplifier.

13. The apparatus recited in claim 12 wherein said tubular envelope and its contained single-channel audio amplifier are removable contained in a chassis of an audio speaker for amplifying signals in said speaker.

14. A multi-channel digital audio signal amplifier comprising a plurality of modules, each such module configured as at least one solid state single-channel amplifier in a tubular configuration and controlled by a controller for dynamically shifting amplifiers based upon the analyzed content of the amplified audio singlas.

15. The amplifier recited in claim 14 wherein said analyzed content is derived a priori and not in real time.

16. A dynamically reconfigurable multi-channel digital audio signal amplifier comprising:
a plurality of single-channel amplifier modules each of which may be functionally re-assigned by an external controller to manage the gain of the amplifier to be operated at its optimum performance parameters; and
a controller for managing the gain of the amplifier by re-assignment of the modules according to a resource plan generated by a priori analysis of the signal content to be amplified.
